(19) United States
(12) Patent Application Publication
(10) Pub. No.: US 2025/0301679 A1
(43) Pub. Date: Sep. 25, 2025

(54) SEMICONDUCTOR DEVICES AND MANUFACTURING METHODS THEREOF

(71) Applicant: Taiwan Semiconductor Manufacturing Company, Ltd., Hsin-Chu (TW)

(72) Inventors: ChiaHung Chou, Hsinchu (TW); Ka-Hing Fung, Hsinchu County (TW); Hsueh-Jen Yang, Taipei City (TW)

(21) Appl. No.: 18/807,456

(22) Filed: Aug. 16, 2024

Related U.S. Application Data
(60) Provisional application No. 63/567,740, filed on Mar. 20, 2024.

(51) Int. Cl. H01L 29/66; H01L 29/06; H01L 29/08; H01L 29/423; H01L 29/775; H01L 29/786

(52) U.S. Cl. CPC H10D 30/014; H10D 30/43; H10D 30/6735; H10D 30/6757; H10D 62/121; H10D 62/151; H10D 64/017; H10D 64/018

(57) ABSTRACT

A method of the present disclosure includes forming over a substrate a stack that includes a plurality of channel layers interleaved by a plurality of sacrificial layers, patterning the stack to form a fin-shaped structure, forming a dummy gate stack over a channel region of the fin-shaped structure, recessing a source/drain region of the fin-shaped structure to form a source/drain trench, selectively removing the sacrificial layers to release the channel layers as channel members, depositing a dielectric dummy layer between the channel members, laterally recessing the dielectric dummy layer to form inner spacer recesses, forming inner spacer features in the inner spacer recesses, forming a source/drain feature in the source/drain region, removing the dummy gate stack, removing the dielectric dummy layer to release the channel members, and forming a gate structure to wrap around each of the channel members.

### PRIORITY DATA

This application claims priority to U.S. Provisional Patent Application No. 63/567,740, filed on Mar. 20, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor. As GAA devices continue to scale, challenges have arisen. For example, the existing structures and fabrication technologies have various issues, which includes excessive impurity diffusion, increased built-in stress, undesired capacitance, device degradation, scaling limit by overlap requirement, and other structure-related issues and/or process-related issues especially as device size is scaled down. Although existing structure and fabrication techniques have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2-29 illustrate fragmentary cross-sectional views of a work-in-progress (WIP) structure during a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

The present disclosure is generally related to GAA transistors and manufacturing methods thereof. GAA transistors may be fabricated using a replacement gate process, where a dummy gate stack is formed first as a placeholder and is subsequently replaced with a functional gate structure. In some replacement gate processes, sacrificial materials among nanostructures of the GAA transistor are removed after epitaxial source/drain features are formed. Ideally, due to the different material compositions, a large etch selectivity between the sacrificial materials (e.g., SiGe) and the nanostructures (e.g., Si) should have safeguarded the nanostructures from etching loss during the removal of the sacrificial materials. However, atoms other than silicon (e.g., Ge) in the sacrificial materials may diffuse into the nanostructures as impurities during annealing processes, such as the annealing processes in forming the epitaxial source/drain features. The diffusion of the impurities lowers the etching selectivity. As a result, the nanostructures may suffer from etching loss during the removal of the sacrificial materials. For example, top and bottom surfaces of the nanostructures may become non-flat and have a curvature profile due to extra etching loss. The curvature profile of the top and bottom surfaces of the nanostructures may cause gate structure profile variation and result in device performance non-uniformity.

The present disclosure provides methods for forming a GAA transistor. In an example process, a fin-shaped structure with channel layers and sacrificial layers is formed over a substrate. After formation of a dummy gate stack over a channel region of the fin-shaped structure, at least one gate spacer is formed over the dummy gate stack. Source/drain regions of the fin-shaped structure are recessed. The sacrificial layers are selectively removed to release the channel layers as channel members. A dielectric dummy layer is then deposited to wrap around each of the channel members. The dielectric dummy layer is then selectively and partially recessed to form inner spacer recesses between the plurality of channel members. An inner spacer layer is deposited over the inner spacer recesses. The deposited inner spacer layer is etched back to form inner spacer features. Source/drain features are then formed over the source/drain recesses. After selective removal of the dummy gate stack, the dielectric dummy layer is selectively removed to release the channel members again. A gate structure is then formed to wrap around each of the channel members.

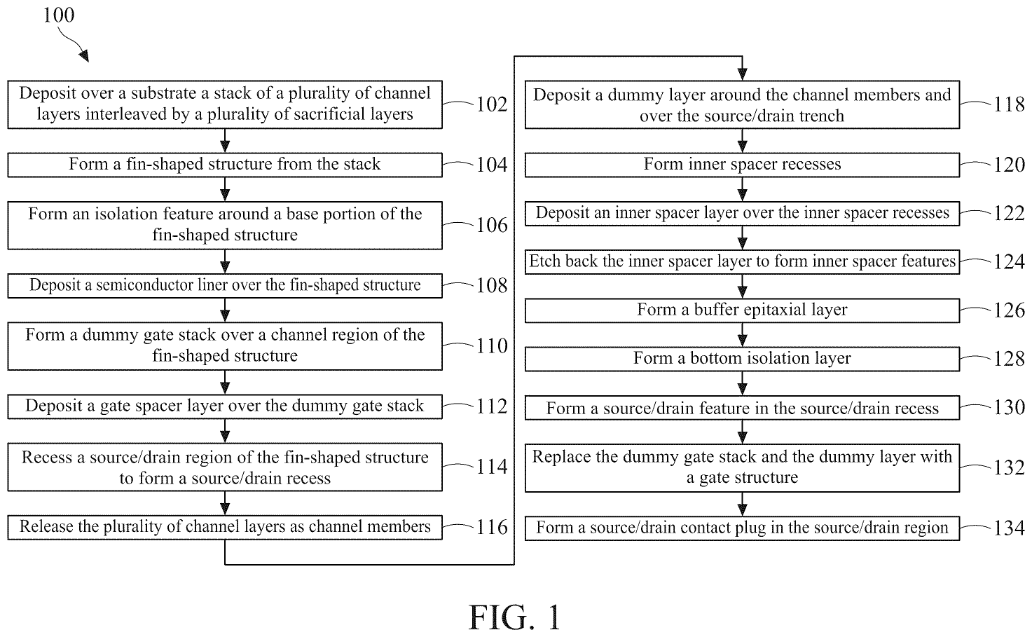

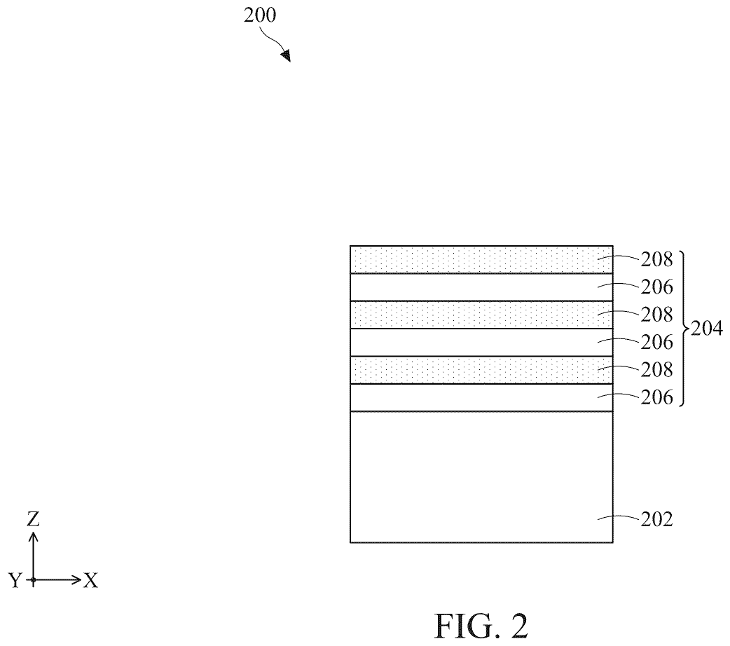

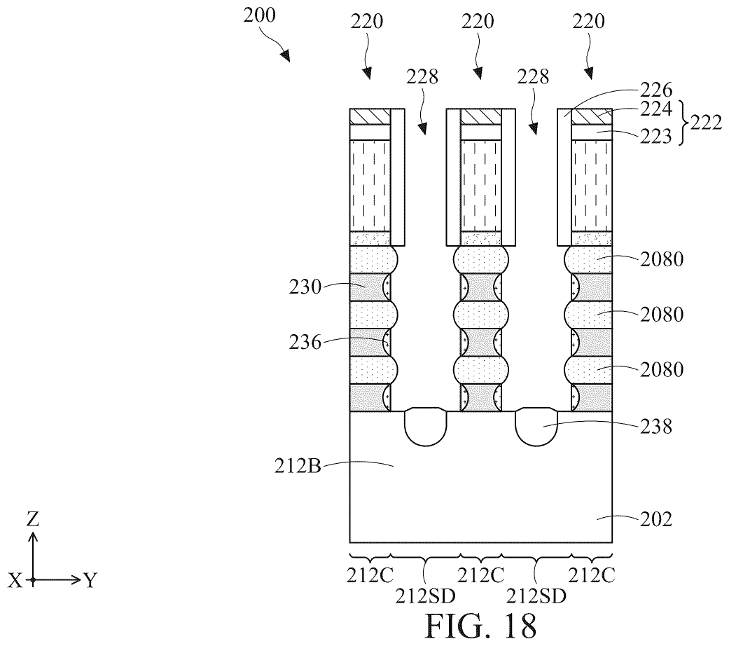

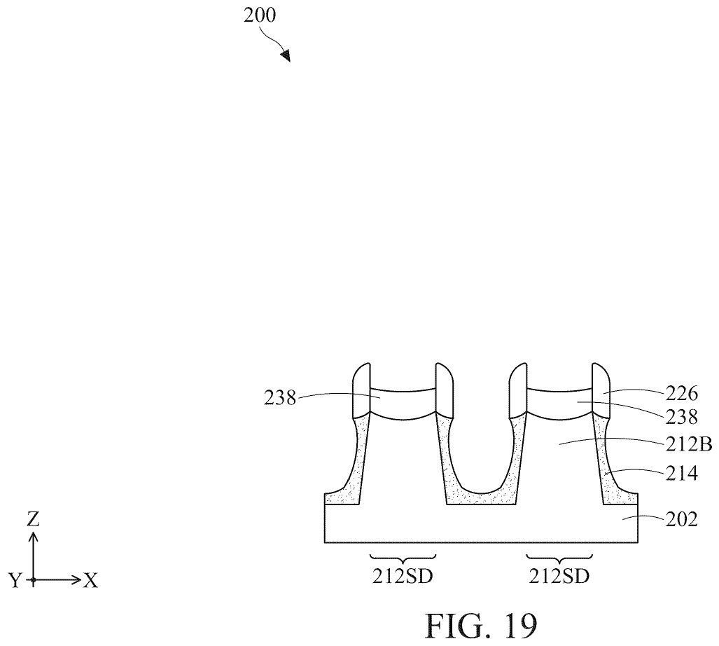

The various aspects of the present disclosure will now be described in more detail with reference to the figures. In that regard, FIG. 1 is a flowchart illustrating method 100 of forming a semiconductor structure from a work-in-progress (WIP) structure according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-29, which are fragmentary cross-sectional views of a WIP structure 200 at different stages of fabrication according to embodiments of the method 100 in FIG. 1. Because the WIP structure 200 will be fabricated into a semiconductor structure or a semiconductor device, the WIP structure 200 is also referred to herein as a semiconductor structure 200 or a semiconductor device 200. For avoidance of doubts, the X, Y and Z directions in FIGS. 2-29 are perpendicular to one another. Throughout the present disclosure, unless expressly described otherwise, like reference numerals denote like features or steps.

Referring to FIGS. 1 and 2, method 100 includes a block 102 where a stack 204 of alternating semiconductor layers is formed over the semiconductor device 200. As shown in FIG. 2, the semiconductor device 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the performance needs for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

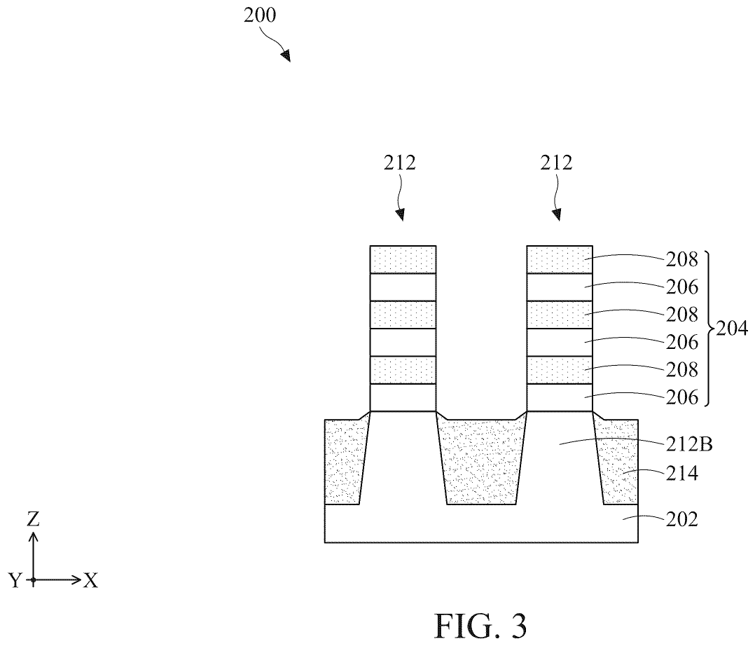

Referring to FIGS. 1 and 3, method 100 includes a block 104 where a fin-shaped structure 212 is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. As shown in FIG. 3, the etching process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 extends vertically along the Z direction and lengthwise along the Y direction. As shown in FIG. 3, the fin-shaped structure 212 includes a fin-shaped base 212B patterned from the substrate 202 and the patterned stack 204 disposed directly over the fin-shaped base 212B. In some instances, a width of the fin-shaped structures 212 measured along the Y direction may be between about 3 nm and about 20 nm.

Still referring to FIGS. 1 and 3, method 100 includes a block 106 where an isolation feature 214 is formed around the fin-shaped base 212B of the fin-shaped structures 212. In some embodiments represented in FIG. 3, the isolation feature 214 is disposed on sidewalls of the fin-shaped base 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the fin-shaped base 212B is embedded or buried in the isolation feature 214.

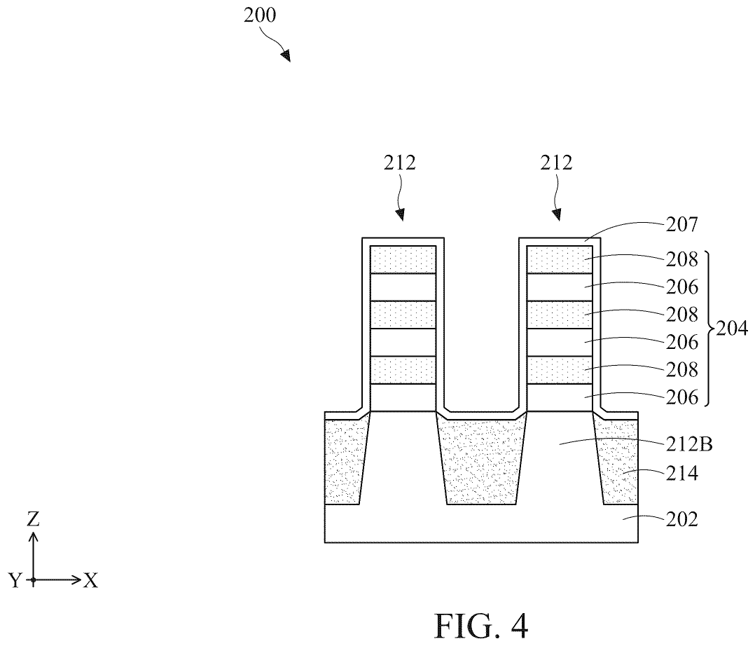

Referring to FIGS. 1 and 4, method 100 includes a block 108 where a semiconductor liner 207 is deposited over the fin-shaped structure 212. After the formation of the isolation feature 214, a semiconductor liner 207 may be deposited over the semiconductor device 200, including over the isolation feature 214, over a top surface of the fin-shaped structure 212, and along sidewalls of the fin-shaped structure 212. The semiconductor liner 207 functions to protect the sidewalls of the sacrificial layers 206 as they can sustain undesirable damages during the fabrication processes. In some embodiments, the semiconductor liner 207 may include silicon (Si). In some implementations, the semiconductor liner 207 may be deposited using PVD, CVD, or atomic layer deposition (ALD).

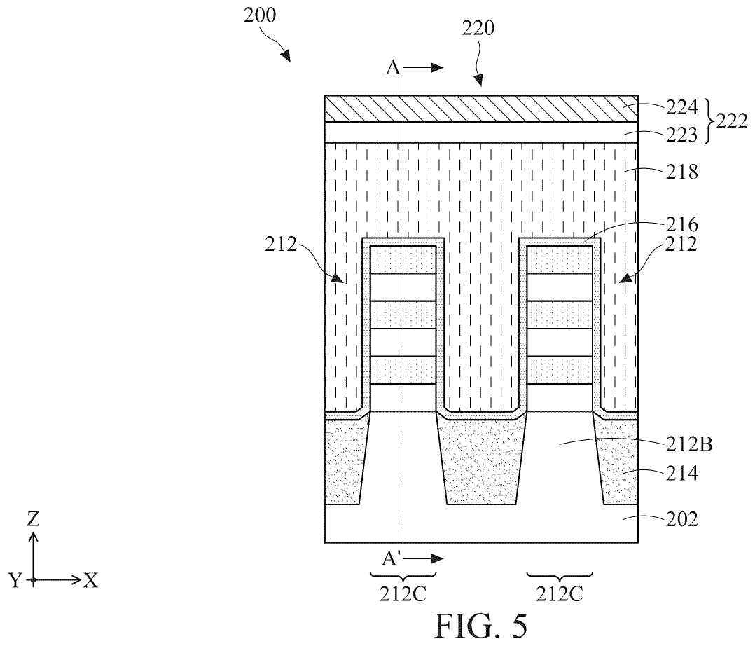

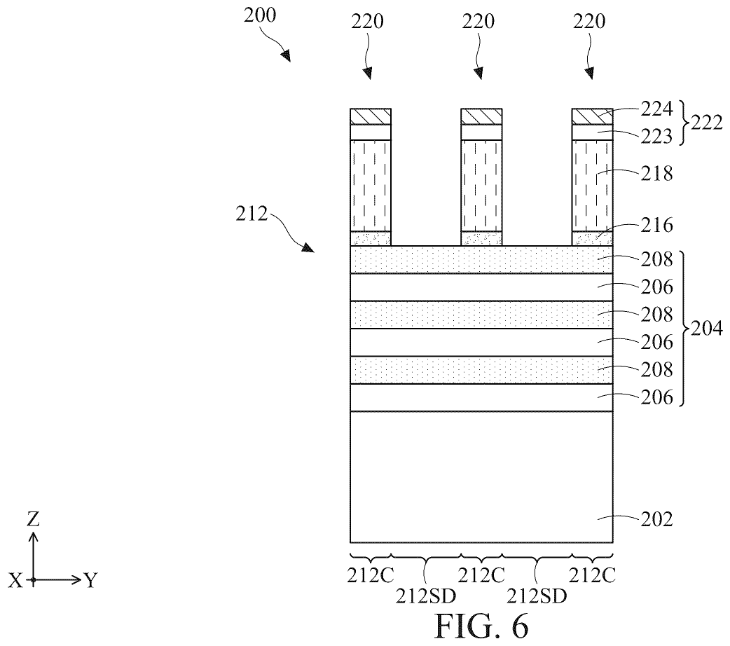

Referring to FIGS. 1 and 5-6, method 100 includes a block 110 where a dummy gate stack 220 is formed over a channel region 212C of the fin-shaped structure 212. The dummy gate stack 220 serves as a placeholder to undergo various processes and is to be removed and replaced by a functional gate structure. Other processes and configuration are possible. FIG. 6 is a cross-sectional view along the A-A line in FIG. 5. In some embodiments as illustrated in FIG. 6, the dummy gate stack 220 is formed over the fin-shaped structure 212, and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 6, the channel region 212C is disposed between two source/drain regions 212SD along the Y direction. As used herein, a source/drain region, or “S/D region,” may refer to a region that provides a source and/or drain for one or multiple devices. It may also refer to a source or a drain of one or multiple devices.

The formation of the dummy gate stack 220 may include deposition of layers in the dummy gate stack 220 and patterning of these layers. Referring to FIG. 5, a dummy dielectric layer 216, a dummy electrode layer 218, and a gate-top hard mask layer 222 may be blanketly deposited over the semiconductor device 200. The dummy dielectric layer 216 may be formed on the fin-shaped structure 212 using a chemical vapor deposition (CVD) process, an ALD process, an oxygen plasma oxidation process, or other suitable processes. In the depicted embodiment, the dummy dielectric layer 216 is formed using an oxygen plasma oxidation process that substantially oxidizes the semiconductor liner 207 to form the dummy dielectric layer 216. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 6. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 6, the dummy gate stack 220 is patterned such that it is only disposed over the channel region 212C, not disposed over the source/drain region 212SD.

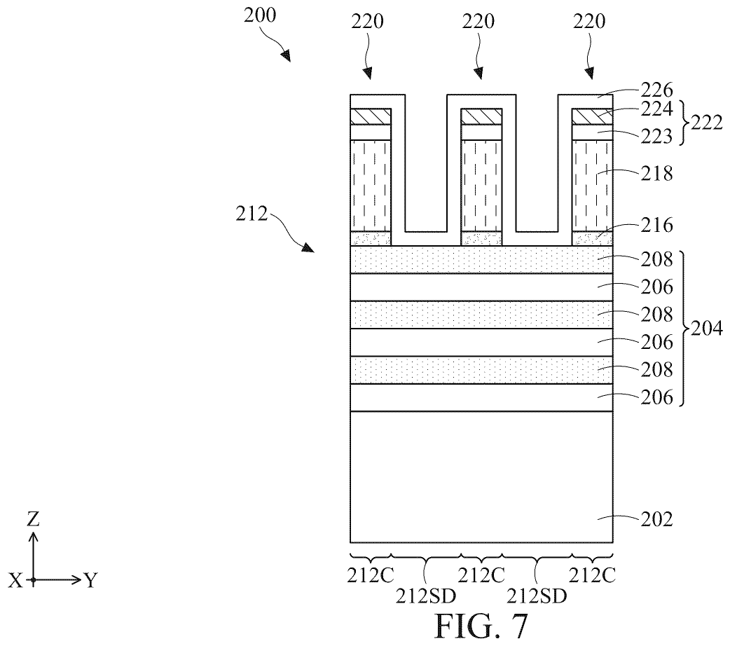

Referring to FIGS. 1 and 7, method 100 includes a block 112 where a gate spacer layer 226 is deposited over the semiconductor device 200, including over the dummy gate stack 220. In some embodiments, the gate spacer layer 226 is deposited conformally over the semiconductor device 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

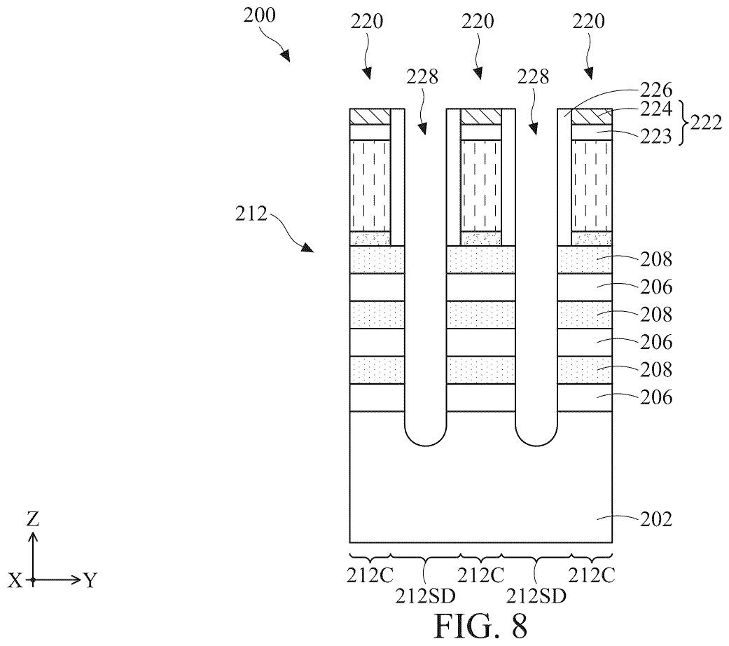

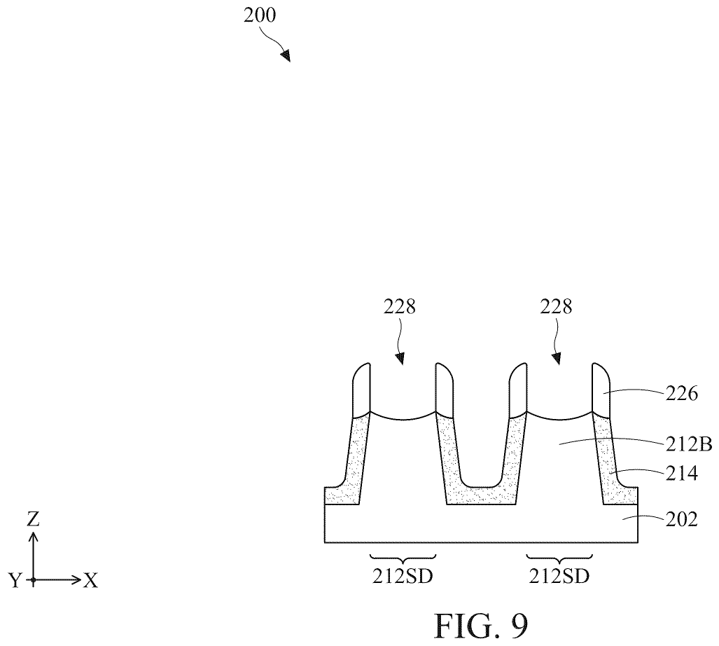

Referring to FIGS. 1 and 8-9, method 100 includes a block 114 where source/drain regions 212SD of the fin-shaped structure 212 are anisotropically recessed to form source/drain trenches 228. The anisotropic etch may include a dry etch or a suitable etching process that etches the source/drain regions 212SD and a portion of the substrate 202. The resulting source/drain trenches 228 extend vertically through the depth of the stack 204 and partially into the substrate 202. An example dry etching process for block 114 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 8, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202. Reference is made to FIG. 9, which includes a fragmentary cross-sectional view across two adjacent source/drain regions 212SD. As shown in FIG. 9, over the source/drain regions 212SD, the majority of the fin-shaped structure 212 is etched away and a top surface of the fin-shaped base 212B is exposed in the source/drain region 212SD. Because the gate spacer layer 226 etches at a slower rate than the fin-shaped structure 212, the gate spacer layer 226 in the source/drain region 212SD rises above the top surface of the fin-shaped base 212B.

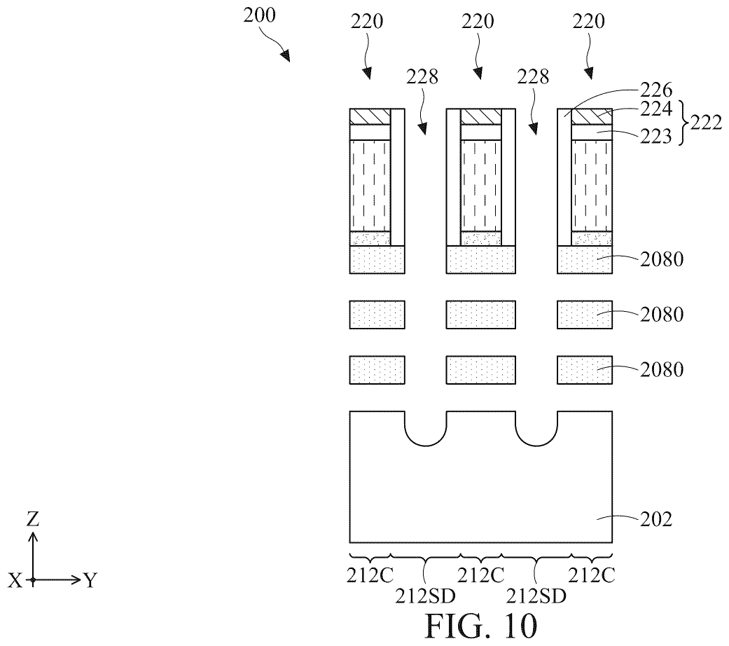

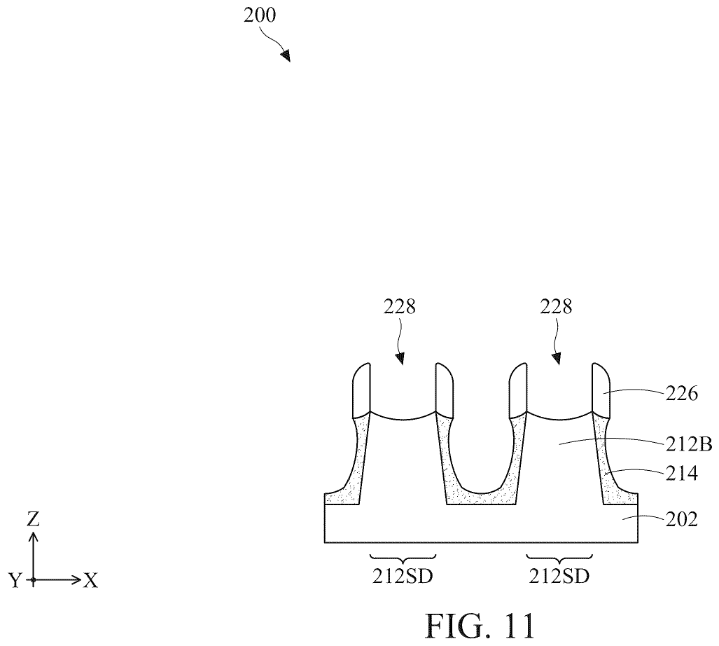

Referring to FIGS. 1 and 10-11, method 100 includes a block 116 where the plurality of channel layers 208 in the channel regions are released as channel members 2080. After the formation of the source/drain trenches 228, the sacrificial layers 206 interleaving the channel layers 208 in the channel region 212C are selectively removed. The selective removal of the sacrificial layers 206 releases the channel layers 208 (shown in FIG. 8) to form channel members 2080 shown in FIG. 10. Depending on the design, the channel members 2080 may take form of nanowires, nanorods, nanosheets, or other nanostructures. The selective removal of the sacrificial layers 206 forms spaces between and around adjacent channel members 2080. The selective removal of the sacrificial layers 206 may be implemented by selective dry etch, selective wet etch, or other selective etching processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Referring to FIG. 11, at block 116, the fin-shaped base 212B in the source/drain regions 212SD remains substantially intact.

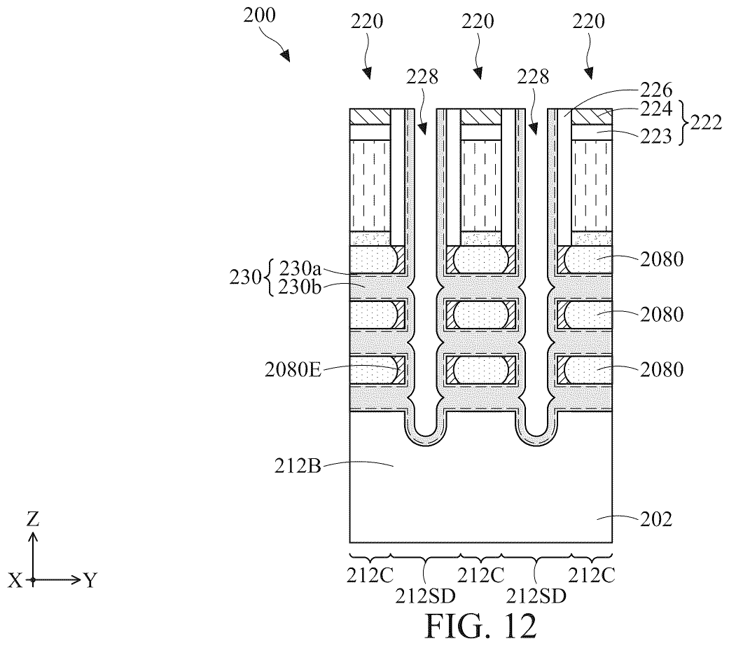

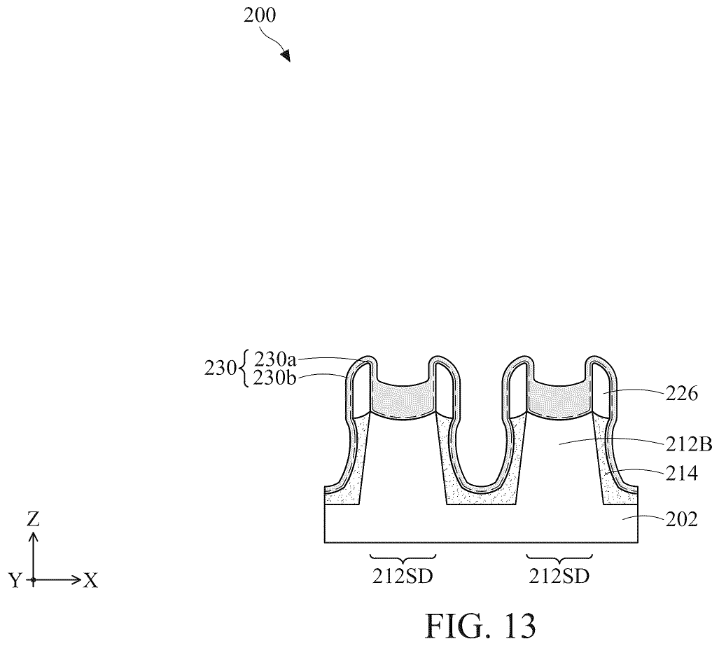

Referring to FIGS. 1 and 12-13, method 100 includes a block 118 where a dielectric dummy layer 230 is deposited around the channel members 2080 and over the source/drain trenches 228. The dielectric dummy layer 230 may be an oxide, such as silicon oxide in some embodiments, and may be deposited using ALD, flowable chemical vapor deposition (FCVD), plasma enhanced chemical vapor deposition (PECVD), or other suitable deposition processes. As shown in FIG. 12, the dielectric dummy layer 230 fills the space among the channel members 2080 and covers sidewalls of the channel members 2080. In the illustrated embodiment, in order to improve the gap fill capability without leaving voids thereunder, the deposition of the dielectric dummy layer 230 may includes an ALD process to first form a thin dielectric layer 230a on various material surfaces (e.g., exposed surfaces of the channel members 2080, fin-shaped base 212B, isolation feature 214, gate spacer layer 226, etc.) and a subsequent FCVD process to form a thick dielectric layer 230b on the now uniform material surface provided by the thin dielectric layer 230a. The combination of the ALD and FCVD processes improves gap fill capability without compromising production throughput. The thin dielectric layer 230a and the thick dielectric layer 230b collectively define the dielectric dummy layer 230. Since the dielectric layers 230a and 230b are both formed of the same dielectric material, such as silicon oxide, an interface therebetween may be not distinctively discernable, which is represented by a dashed line in FIGS. 12 and 13. Yet, due to the different deposition processes, the thin dielectric layer 230a deposited by an ALD process may have a higher density than the thick dielectric layer 230b deposited by an FCVD process.

Additionally, as illustrated in FIG. 12, end portions of the channel members 2080 may be oxidized during operations at block 118. The oxidation may be due to the channel members 2080 being exposed in the oxygen rich environment during the deposition of the dielectric dummy layer 230 and also due to the diffusion of the oxygen atoms from the thin dielectric layer 230a into the end portions of the channel members 2080. As a result, oxide-containing end portions 2080E are formed on the lateral ends of the channel members 2080, and the thin dielectric layer 230a may have a lower oxygen concentration (and thus a higher silicon concentration if silicon oxide is deposited at block 118, and accordingly a higher density) than the thick dielectric layer 230b.

The dielectric dummy layer 230 is in direct contact with a sidewall of the gate spacer layer 226 and a top surface of the substrate 202. Reference is made to FIG. 13, which includes a fragmentary cross-sectional view across two adjacent source/drain regions 212SD. The dielectric dummy layer 230 extends over the isolation feature 214, sidewalls of the gate spacer layer 226, and top surfaces of the gate spacer layer 226. Because the source/drain trench 228 extends into the substrate 202, a thickness of the dielectric dummy layer 230 at the bottom of the source/drain trench 228 may be greater than a thickness of the dielectric dummy layer 230 along sidewalls of the channel members 2080. For the sake of simplicity, in the following figures, the dielectric layers 230a and 230b may not be individually shown but represented collectively as the dielectric dummy layer 230, unless otherwise indicated separately.

A cleaning process may optionally be performed at the conclusion of block 118. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and/or hydrofluoric acid for oxide removal. The dry clean process may include helium (He) and hydrogen (H2) treatment. The hydrogen treatment may convert silicon debris on the exposed surfaces to silane (SiH₄), which may be pumped out for removal.

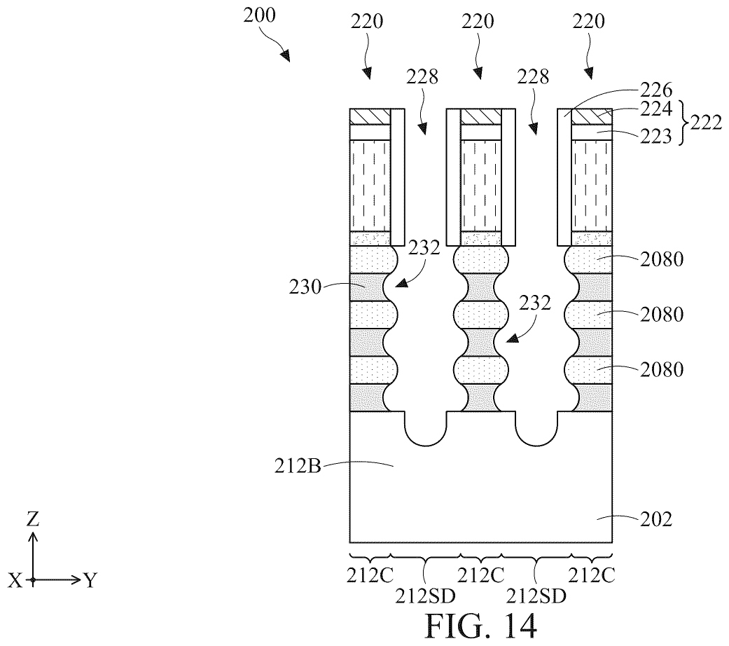

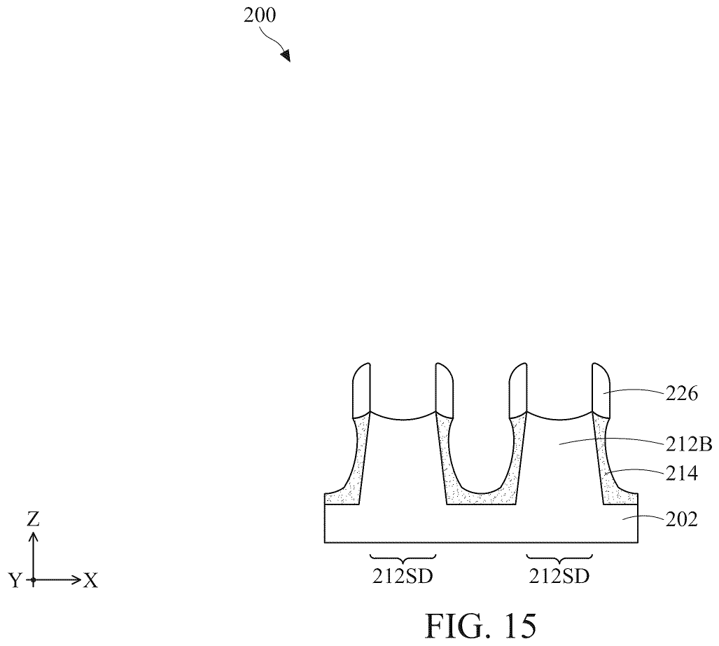

Referring to FIGS. 1 and 14-15, method 100 includes a block 120 where inner spacer recesses 232 are formed. Referring to FIG. 14, the dielectric dummy layers 230 are selectively and partially recessed to form inner spacer recesses 232. The inner spacer recesses 232 may have a concave profile bending away from the source/drain trenches 228. The oxide-containing end portions 2080E of the channel members 2080 are also removed at block 120, while the gate spacer layer 226, the dummy gate stack 220, the exposed portion of the substrate 202, and the center portions of the channel members 2080 are substantially unetched. The removal of the end portions 2080E reduces the length of the channel members 2080. In the depicted embodiment as shown in FIG. 14, the end points of the channel members 2080 retreat from a vertical plane containing an outer sidewall of the gate spacer layer 226. In an embodiment where the channel members 2080 consist essentially of silicon and the dielectric dummy layers 230 are formed of silicon oxide, the selective recess of the dielectric dummy layer 230 may be performed using a selective wet etching process or a selective dry etching process. An example selective wet etching process may include use of diluted hydrofluoric acid (DHF) or a mixture of hydrofluoric acid (HF) and, ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. As shown in FIG. 15, the dielectric dummy layer 230 is removed from the source/drain regions 212SD, and the fin-shaped base 212B is exposed.

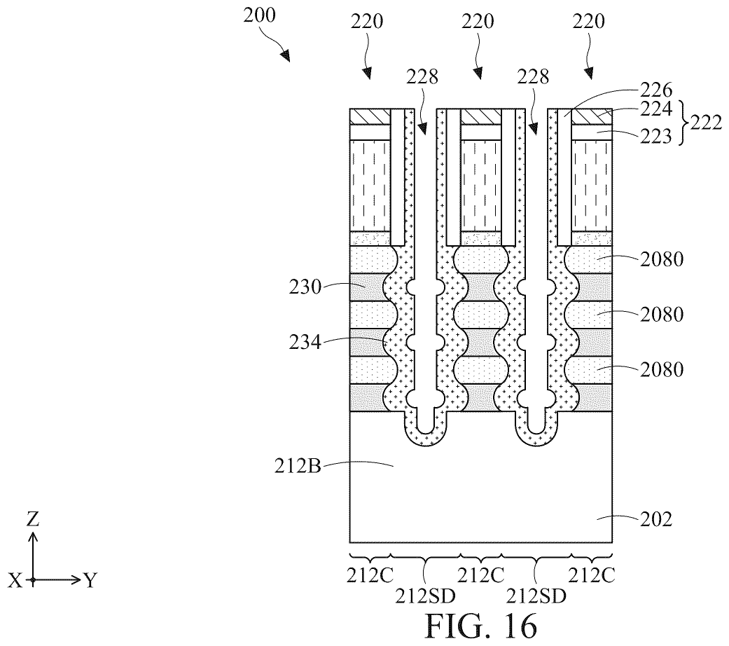

Referring to FIGS. 1 and 16, method 100 includes a block 122 where an inner spacer layer 234 is deposited over the inner spacer recesses 232. A composition of the inner spacer layer 234 is different from a composition of the dielectric dummy layer 230 to ensure that each one of them may be selectively etched without substantially damaging the other one. In some embodiments, the inner spacer layer 234 may include silicon carbonitride (SiCN), silicon oxycarbonitride (SiOCN), silicon nitride (SiN), silicon oxycarbide (SiOC), or silicon oxynitride (SiON). In some implementations, the inner spacer layer 234 may be deposited using CVD or ALD.

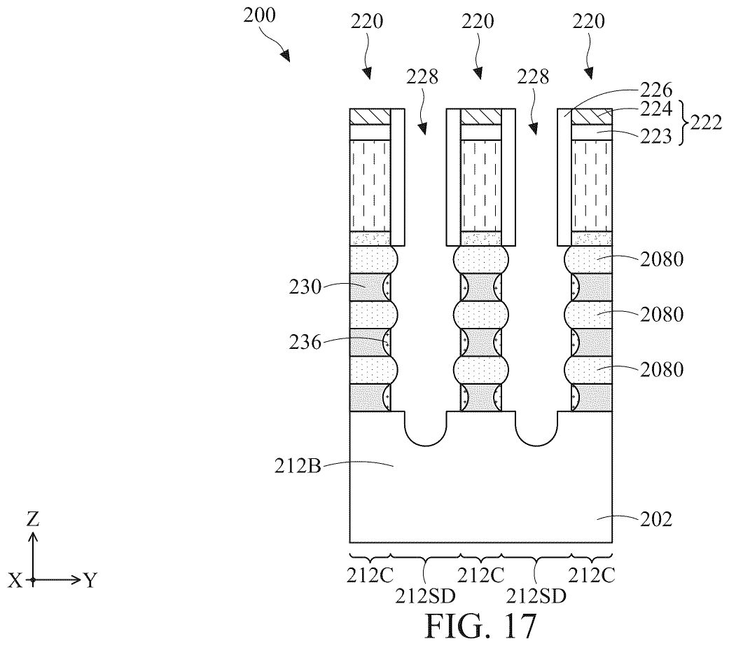

Referring to FIGS. 1 and 17, method 100 includes a block 124 where the inner spacer layer 234 is etched back to form inner spacer features 236 over the inner spacer recesses 232. In some embodiments, the etching back at block 124 may include use of a dry etching process, such as a reactive ion etching (RIE) process that is aided by plasma. An example dry etching process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In some embodiments, the length of the inner spacer features 236 measured along the Y direction increases from top to bottom. This increase is likely due to a higher lateral etching rate of the dielectric dummy layers 230 where it is closer to the bottom of the source/drain trench 228. Consequently, this results in larger inner spacer recesses 232 from top to bottom upon completion of previous operations at block 120.

Referring to FIGS. 1 and 18-19, method 100 includes a block 126 where a buffer epitaxial layer 238 is deposited in the bottom of the source/drain trenches 228. The buffer epitaxial layer 238 is epitaxially grown from the top surface of the fin-shaped base 212B. By way of example, epitaxial growth of the buffer epitaxial layer 238 may be performed by VPE, ultra-high vacuum CVD (UHV-CVD), MBE, and/or other suitable epitaxial grow processes. In some embodiments, the buffer epitaxial layer 238 includes the same material as the substrate 202, such as silicon. In some alternative embodiments, the buffer epitaxial layer 238 includes a different semiconductor material other than silicon, such as SiGe, SiSn, or other suitable semiconductor material. In some embodiments, the buffer epitaxial layer 238 is dopant-free, where for example, no intentional doping is performed during the epitaxial growth process. As a comparison, in one instance, the substrate 202 is lightly doped and has a higher doping concentration than the buffer epitaxial layer 238. The buffer epitaxial layer 238 provides a high resistance path from the S/D regions to the semiconductor substrate, such that the leakage current in the semiconductor substrate is suppressed.

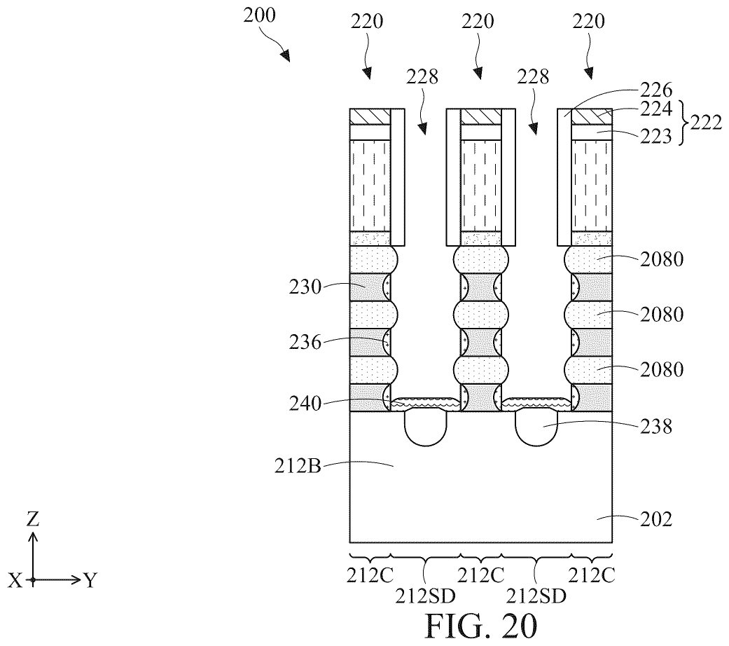

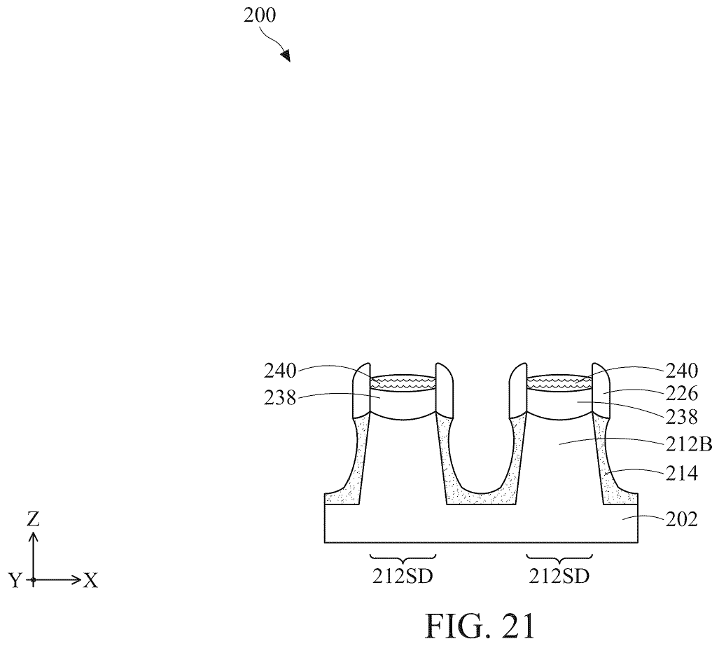

Referring to FIGS. 1 and 20-21, method 100 includes a block 128 where a bottom isolation layer 240 is formed over the buffer epitaxial layer 238. Because the bottom isolation layer 240 may interface source/drain features and oxygen content may oxidize source/drain features, the bottom isolation layer 240 may be formed of an oxygen-free dielectric material, such as nitrogen. In an example process, a chlorine-containing silicon nitride layer is deposited over the source/drain trenches 228, including over a top surface of the buffer epitaxial layer 238. The chlorine-containing silicon nitride layer may be deposited using ammonia (NH₃) and a chlorine-containing silicon precursor, such as silicon tetrachloride (SiCl₄), dichlorodisilane (Si₂H₄Cl₂), dichlorosilane (SiH₂Cl₂), or hexachlorodisilane (Si₂Cl₆). The chlorine-containing silicon nitride layer may be deposited using plasma-enhanced atomic layer deposition (PEALD) or thermal ALD. A directional plasma treatment process is then performed to remove chlorine from a bottom portion of the chlorine-containing silicon nitride layer. In some embodiments, the directional plasma treatment may include use of an argon (Ar) plasma, a nitrogen (N₂) plasma, and/or a hydrogen (H₂) plasma. After the directional plasma treatment, a dry etching process using fluorine-containing etchant (e.g., trifluoromethane (CHF₃), nitrogen trifluoride (NF₃), hydrogen (H₂), ammonia (NH₃), carbon tetrafluoride (CF₄), or sulfur hexafluoride (SF₆)) may be performed. Because the dry etching process etches the chlorine-containing silicon nitride along sidewalls faster than it does relatively chlorine-free silicon nitride layer at the bottom of the source/drain trenches 228, the bottom isolation layer 240 may be formed over the buffer epitaxial layer 238, as shown in FIGS. 20 and 21.

Referring to FIGS. 1 and 22-23, method 100 includes a block 130 where a source/drain feature 244 is formed over the source/drain region 212SD. While not explicitly shown, before any of the epitaxial layers are formed, method 100 may include a cleaning process to clean surfaces of the semiconductor device 200. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment.

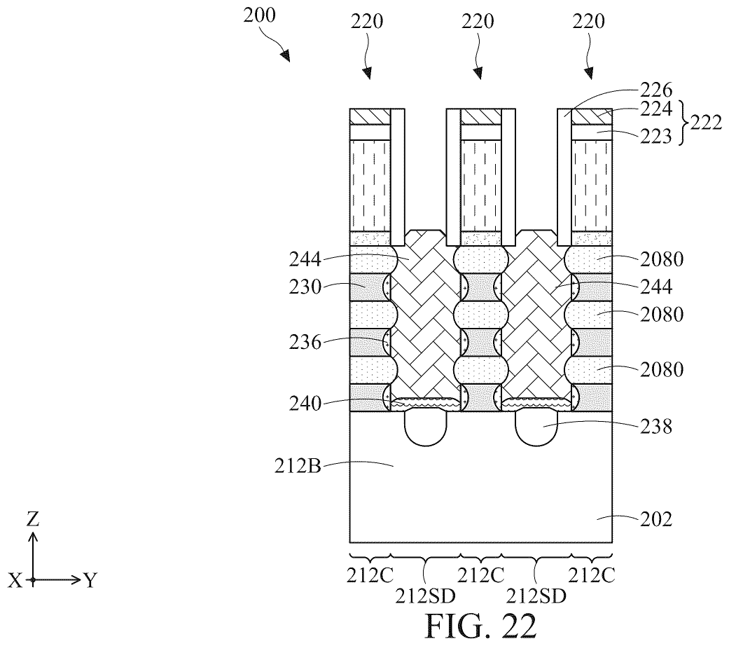

Reference is made to FIG. 22. The source/drain feature 244 may be n-type or p-type. When the source/drain feature 244 is n-type, the source/drain feature 244 may include silicon (Si) and an n-type dopant, such as phosphorus (P), arsenic (As), antimony (Sb), or a combination thereof. When the source/drain feature 244 is p-type, the source/drain feature 244 may include silicon germanium (SiGe) and a p-type dopant, such as boron (B), boron difluoride (BF₂), or a combination thereof. While not explicitly shown in the figures, in some embodiments, the source/drain feature 244 may include multiple layers. For example, the source/drain feature 244 may include a lightly doped epitaxial feature over the bottom isolation layer 240 and a heavily doped epitaxial feature over the lightly doped epitaxial feature. The lightly doped epitaxial feature includes smaller dopant concentration and impurity concentration to reduce crystalline defects. The heavily doped epitaxial feature accounts for a majority of the volume to reduce contact resistance. The source/drain feature 244 may be formed using vapor-phase epitaxy (VPE), ultra-high vacuum CVD (UHV-CVD), or molecular beam epitaxy (MBE). Doping of the source/drain features 244 may be achieved with in-situ doping. As the oxidized end portions of the channel members 2080 are removed in the previous processes and the end points of the channel members 2080 retreat from the outer sidewall of the gate spacer layer 226, a portion of the bottom surface of the gate spacer layer 226 is exposed and in direct contact with the source/drain features 244.

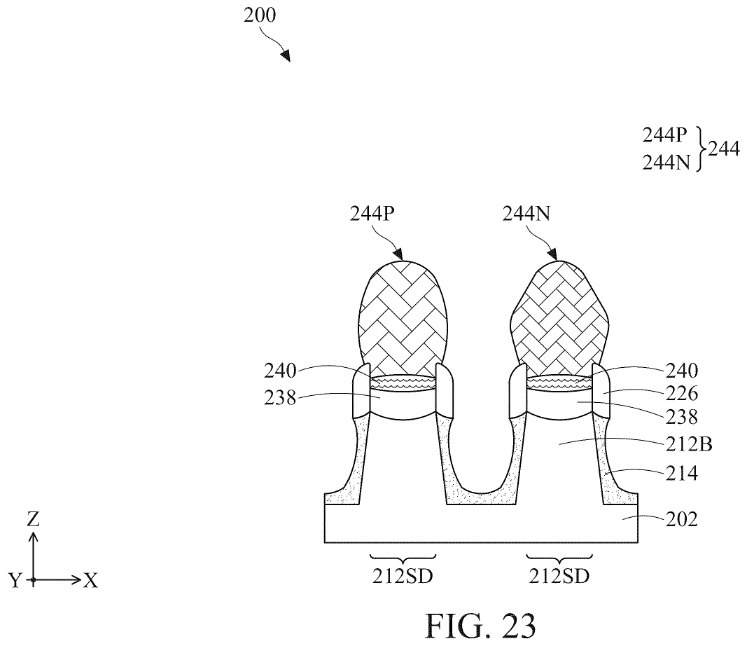

Reference is made to FIG. 23, which includes a fragmentary cross-sectional view across two adjacent source/drain regions 212SD. In some embodiments represented in FIG. 23, an n-type source/drain feature 244N may be adjacent a p-type source/drain feature 244P. The n-type source/drain feature 244N may include silicon (Si) and an n-type dopant, such as phosphorus (P), arsenic (As), or antimony (Sb). The p-type source/drain feature 244P may include silicon germanium (SiGe) and a p-type dopant, such as boron (B). Each of the n-type source/drain feature 244N and the p-type source/drain feature 244P may be in direct contact with a top surface of the bottom isolation layer 240. For ease of illustration and description, the n-type source/drain feature 244N and the p-type source/drain feature 244P may be collectively referred to as the source/drain feature 244, as in FIG. 22.

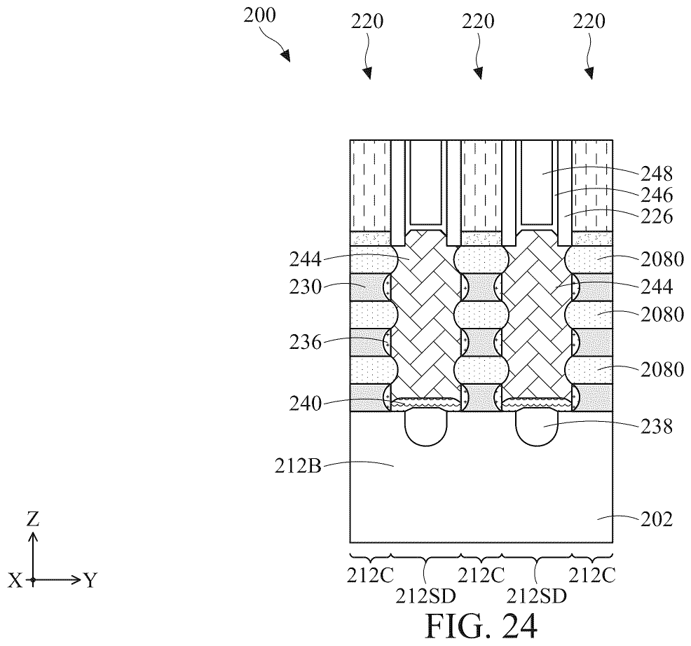

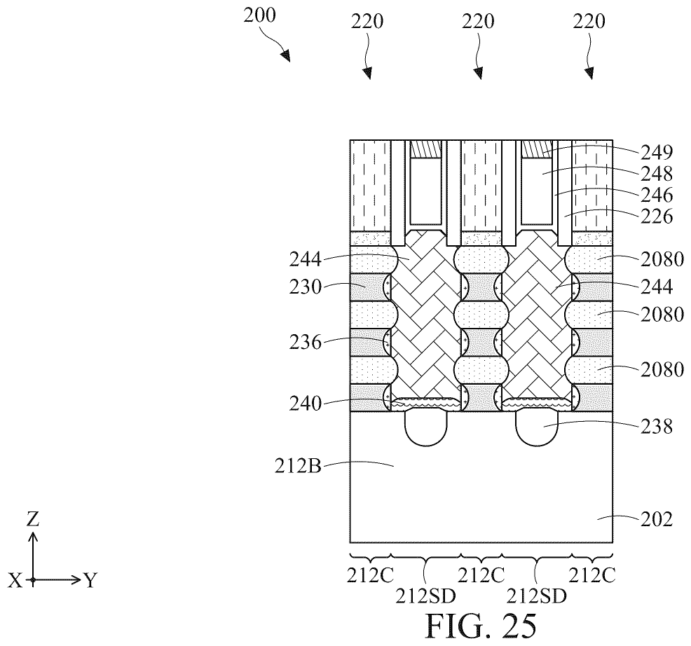

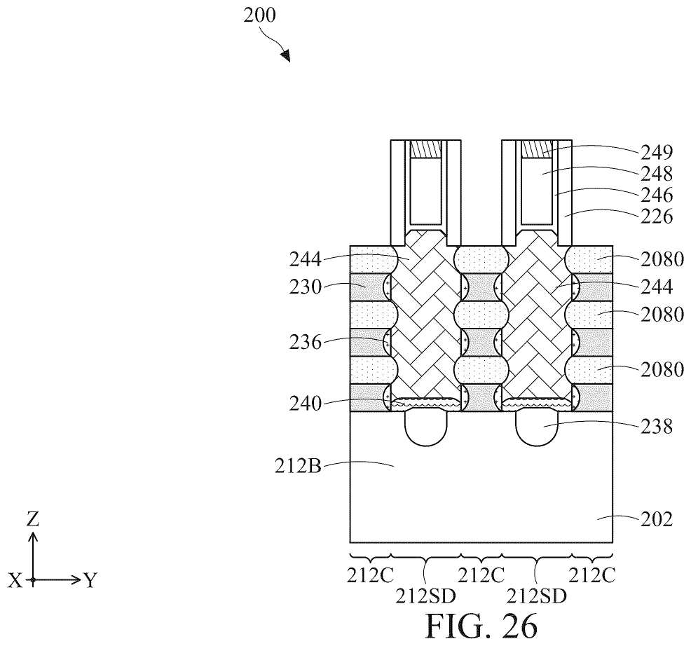

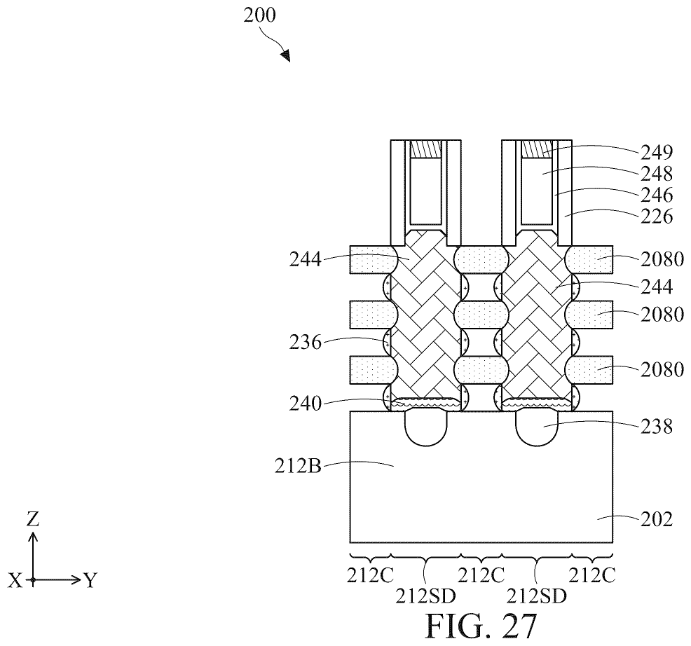

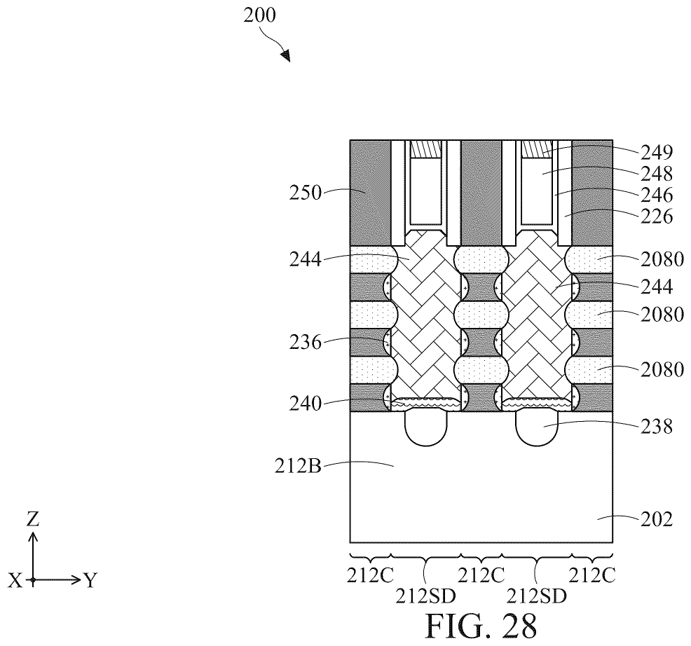

Referring to FIGS. 1 and 24-28, method 100 includes a block 132 where the dummy gate stack 220 and the dielectric dummy layer 230 are replaced with a gate structure 250. Operations at block 132 may include deposition of a contact etch stop layer (CESL) 246 over the source/drain features 244 (shown in FIG. 24), deposition of an interlayer dielectric (ILD) layer 248 over the CESL 246 (shown in FIG. 24), deposition of a capping layer 249 over the ILD layer 248 (shown in FIG. 25), removal of the dummy gate stack 220 (shown in FIG. 26), removal of the dielectric dummy layer 230 (shown in FIG. 27), and deposition of the gate structure 250 to wrap around each of the channel members 2080 (shown in FIG. 28). Referring to FIG. 24, the CESL 246 is deposited over the semiconductor device 200, including over the source/drain feature 244. The CESL 246 may include silicon nitride or aluminum nitride. In some implementations, the CESL 246 may be deposited using CVD or atomic layer deposition (ALD). The ILD layer 248 is then deposited over the CESL 246. In some embodiments, the ILD layer 248 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 248 may be deposited using CVD, flowable CVD (FCVD), spin-on coating, or a suitable deposition technique. After the deposition of the ILD layer 248, the semiconductor device 200 may be planarized by a planarization process to remove the gate-top hard mask layer 222 and expose the dummy gate stack 220. For example, the planarization process may include a chemical mechanical planarization (CMP) process.

In order to protect the ILD layer 248 from being damaged during the dielectric dummy layer 230 removal step, the ILD layer 248 is selectively recessed to form a top recess and a capping layer 249 is formed over the top recess. The capping layer 249 is formed of a different material than the dielectric dummy layer 230. When the dielectric dummy layer 230 includes silicon oxide, the capping layer 249 is not formed of silicon oxide so as to ensure etching selectivity. In some embodiments, the capping layer 249 may include silicon nitride, silicon carbonitride, silicon carbide, or silicon oxycarbonitride. In one embodiment, the capping layer 249 may include silicon nitride. Another planarization is performed to remove excess capping layer 249 and to expose the dummy gate stack 220. After the planarization, top surfaces of the capping layer 249, the CESL 246, the gate spacer layer 226, and the dummy gate stacks 220 are coplanar. Exposure of the dummy gate stack 220 allows the removal thereof. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220.

After the removal of the dummy gate stack 220, the dielectric dummy layer 230 in the channel region 212C is exposed, as shown in FIG. 26. A separate etching process may be performed to selectively remove the dielectric dummy layer 230 in the channel region 212C. For example, a selective wet etching process or a selective dry etching process may be performed to remove the dielectric dummy layer 230. An example selective wet etching process may include use of diluted hydrofluoric acid (DHF) or a mixture of hydrofluoric acid (HF) and ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. By design, the etch selectivity of the dielectric dummy layer 230 over the channel members 2080 may be larger than about 1000:1, such that the channel members 2080 remain substantially intact. After the selective removal of the dielectric dummy layer 230, the channel members 2080 in the channel region 212C are once again exposed as shown in FIG. 27.

After the release of the channel members 2080, the gate structure 250 is formed to wrap around each of the channel members 2080 as shown in FIG. 28. The gate structure 250 is also referred to as metal gate structure 250 due to its metal-containing layers. While not explicitly shown, the gate structure 250 includes an interfacial layer interfacing the channel members 2080 and the substrate 202 in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 250 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAIN), tantalum nitride (TaN), tantalum aluminum (TaAl), tantalum aluminum nitride (TaAIN), tantalum aluminum carbide (TaAIC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure 250 includes portions that interpose between channel members 2080 in the channel region 212C. In some embodiments, the gate structure 250 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080.

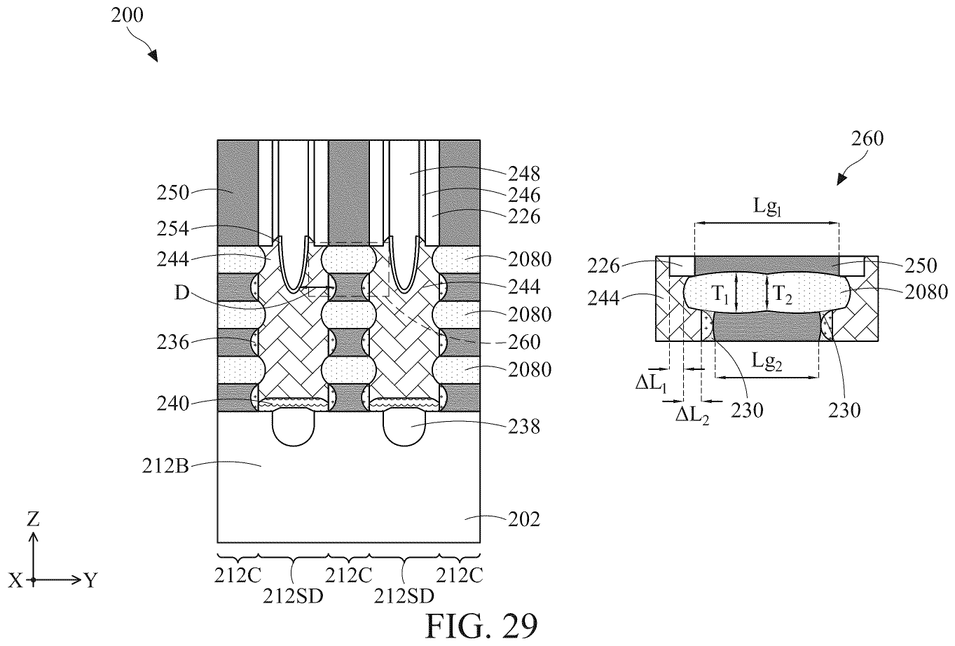

Referring to FIGS. 1 and 29, method 100 includes a block 134 where source/drain contact plugs 252 and optional silicide features 254 between the source/drain contact plugs 252 and the source/drain feature 244 are formed in the source/drain regions 212SD. In an exemplary process, contact holes are first formed by etching through the capping layer 249, the ILD layer 248, and the CESL 246. The etching process may be a self-aligned process such that the capping layer 249 and the ILD layer 248 are removed using the vertical sidewalls of the CESL 246 as an etch stop layer. An upper portion of the source/drain feature 244 may optionally be etched to have a concave shape as a bottom of the contact hole. In the depicted embodiment, the source/drain feature 244 is recessed to a position below the bottom surface of the topmost channel member 2080. The silicide features 254 are formed at the bottom of the contact holes. The silicide features 254 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. Subsequently, source/drain contact plugs 252 are formed on the silicide features 254. Each source/drain contact plug 252 may include a conductive barrier layer and a bulk metal layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The bulk metal layer may include tungsten (W), cobalt (Co), molybdenum (Mo), ruthenium (Ru), nickel (Ni), copper (Cu), or other metals, and may be formed by CVD, PVD, ALD, plating, or other suitable processes. The silicide feature 254 and the source/drain contact plug 252 may be collectively referred to as the source/drain contact.

Still referring to FIG. 29, a region 260 is enlarged to illustrate some structural details of the semiconductor device 200. The region 260 includes one of the channel members 2080 and its neighboring features. In the illustrated embodiment, the top and bottom surfaces of the channel member 2080 each have a curvature profile, which is due to some etching loss during the release of the channel members 2080. Due to the curvature profile, a thickness denoted as T₂ measured at a midpoint of the channel member 2080 (also considered as its smallest thickness) is generally thinner than its largest thickness denoted as T₁. Conventionally, the channel members 2080 are released by removing sacrificial layers 206. Yet, atoms other than silicon in the sacrificial materials (e.g., Ge) may have diffused into the channel members 2080 as impurities during annealing processes in forming the source/drain feature 244. The diffusion of impurities lowers the etching selectivity. As a result, the channel members 2080 may suffer from certain etching loss during the removal of the sacrificial materials. For example, T₂ may be less than about 90% of T₁ (i.e., T₂<0.9*T₁), or stated differently a difference between T₁ and T₂ may be at least 10% of T₁ (i.e., T₁−T₂>0.1*T₁). Such variation deteriorates device performance uniformity. As a comparison, in the present disclosure, the sacrificial layers 206 have been replaced by the dielectric dummy layer 230 (as shown in FIGS. 12 and 14) prior to the subsequent annealing processes, which hampers the impurity diffusion. Consequently, the channel members 2080 are released by removing the dielectric dummy layer 230. An etching selectivity between the dielectric dummy layer 230 and the channel members 2080 is significantly larger than an etching selectivity between the sacrificial layer 206 and the channel members 2080. As a result, the thickness of the channel members 2080 becomes much more consistent. For example, in the present disclosure, T₂ is larger than about 95% of T₁ (i.e., T₂>0.95*T₁), or stated differently a difference between T₁ and T₂ is less than about 5% of T₁ (i.e., T₁−T₂<0.05*T₁). In one instance, a ratio between T₂ over T₁ is between about 95% and about 98% (0.95<T₂/T₁<0.98). This range is not arbitrary or trivial. If the ratio is less than about 95%, the device performance uniformity starts to be compromised; if the ratio is larger than about 98%, the extra manufacturing cost to maintain tightly controlled process windows may become not economical.

A portion of the dielectric dummy layer 230 may optionally remain in the corner regions adjacent the concave surface of the inner spacer features 236, as it may be difficult for an etching process to reach those niche areas. Alternatively, the dielectric dummy layer 230 may be completely removed, and the corner regions are filled with the gate structure 250. If residues of the dielectric dummy layer 230 remain in the corner regions, the inner spacer features 236 and the residues of the dielectric dummy layer 230 collectively separate the gate structure 250 from the source/drain feature 244. In one example, the inner spacer features 236 includes silicon nitride, and the residues of the dielectric dummy layer 230 includes silicon oxide. As discussed above with reference to FIG. 12, the residues of the dielectric dummy layer 230 may also include a first dielectric layer 230a formed in an ALD process and a second dielectric layer 230b formed in an FCVD process. The first dielectric layer 230a is in direct contact with the channel members 2080. The second dielectric layer 230b is in direct contact with the inner spacer features 236. The first dielectric layer 230a is thinner than the second dielectric layer 230b. The first dielectric layer 230a also has a higher density, higher silicon concentration in atomic percentage, and lower oxygen concentration in atomic percentage than the second dielectric layer 230b. In one instance, the second dielectric layer 230b essentially includes SiO₂, and the first dielectric layer 230a essentially includes SiOₓ with x between about 1.2 and about 1.8.

Further, as discussed above, lateral ends of the channel members 2080 may be laterally recessed during the replacement of the sacrificial layer 206 with the dielectric dummy layer 230. As a result, the end points of the channel members 2080 may retreat from an outer sidewall of the gate spacer layer 226 for a lateral distance, denoted as ΔL₁. An outer sidewall of the inner spacer feature 236 may further retreat from the end points of the channel members 2080 for a lateral distance, denoted as ΔL₂. In some instances, ΔL₁ is less than ΔL₂; in some other instances, ΔL₁ is larger than ΔL₂, which depends on device performance needs. With these lateral offsets, the potion of the gate structure 250 stacked between the channel members 2080 has a reduced width, denoted as Lg₂. The upper portion of the gate structure 250 has a width defined by lateral distance between opposing sidewalls of the gate spacer layer 226, denoted as Lg₁, which is larger than the reduced width Lg₂. In some embodiments, a ratio of Lg₂/Lg₁ is between about 0.8 and about 0.95. The reduced width Lg₂ increases the lateral distance D between the gate structure 250 and the adjacent source/drain contact plug 252, which effectively reduces parasitic capacitance therebetween and improves transistor DC performance.

Although not intended to be limiting, embodiments of the present disclosure provide one or more of the following advantages. For example, embodiments of the present disclosure replace germanium-containing sacrificial layers with oxide-containing dielectric dummy layers. During a replacement gate process, the dielectric dummy layers are selectively removed to release the channel members. A metal gate structure is then formed to wrap around each of the channel members. Such a process increases the etching contrast during the release of the channel members and improves the profile uniformity in the channel region of a GAA transistor. Further, embodiments of the present disclosure can be readily integrated into existing semiconductor manufacturing processes.

In one exemplary aspect, the present disclosure is directed to a method. The method includes forming over a substrate a stack that includes a plurality of channel layers interleaved by a plurality of sacrificial layers, patterning the stack to form a fin-shaped structure, forming a dummy gate stack over a channel region of the fin-shaped structure, depositing a gate spacer layer over the dummy gate stack, after the depositing of the gate spacer layer, recessing a source/drain region of the fin-shaped structure to form a source/drain trench, selectively removing the plurality of sacrificial layers in the channel region to release the plurality of channel layers as a plurality of channel members, depositing a dielectric dummy layer between the plurality of channel members, laterally recessing the dielectric dummy layer to form inner spacer recesses, depositing an inner spacer layer over the inner spacer recesses, etching back the inner spacer layer to form inner spacer features in the inner spacer recesses, forming a source/drain feature in the source/drain region, after the forming of the source/drain feature, removing the dummy gate stack, removing the dielectric dummy layer to release the plurality of channel members, and forming a gate structure to wrap around each of the plurality of channel members. In some embodiments, the dielectric dummy layer includes silicon oxide. In some embodiments, during the depositing of the dielectric dummy layer, end portions of the plurality of channel members are oxidized. In some embodiments, the laterally recessing of the dielectric dummy layer also laterally recesses the oxidized end portions of the plurality of channel members. In some embodiments, during the laterally recessing of the dielectric dummy layer, a bottom surface of the gate spacer layer is exposed. In some embodiments, the source/drain feature is in contact with the bottom surface of the gate spacer layer. In some embodiments, the method further includes depositing a contact etch stop layer (CESL) over the source/drain feature, depositing an interlayer dielectric (ILD) layer over the CESL, selectively recessing the ILD layer to form a top recess, and depositing a capping layer over the top recess. In some embodiments, a composition of the capping layer is different from a composition of the dielectric dummy layer. In some embodiments, the gate structure has an upper portion laterally stacked between opposing sidewalls of the gate spacer layer and a lower portion vertically stacked between two adjacent ones of the plurality of channel members, and a first width of the upper portion of the gate structure is larger than a second width of the lower portion of the gate structure. In some embodiments, a ratio of the second width over the first width is between about 0.8 and about 0.95.

In another exemplary aspect, the present disclosure is directed to a method. The method includes forming a stack that includes a plurality of first semiconductor layers of a first semiconductor material interleaved by a plurality of second semiconductor layers of a second semiconductor material that is different from the first semiconductor material, patterning the stack to form a fin-shaped structure, forming a dummy gate stack over a first region of the fin-shaped structure, depositing a gate spacer layer over sidewalls of the dummy gate stack, after the depositing of the gate spacer layer, recessing a second region of the fin-shaped structure to form a first trench, selectively removing the second semiconductor layers in the first region to release the first semiconductor layers, depositing an oxide layer in space among the first semiconductor layers, partially recessing the oxide layer to form inner spacer recesses, forming inner spacer features in the inner spacer recesses, forming a source/drain feature in the first trench, removing the dummy gate stack to form a second trench, selectively removing the oxide layer from the second trench, and forming a gate structure in the second trench to engage the first semiconductor layers. In some embodiments, the depositing of the oxide layer includes depositing a first oxide layer in a first deposition process and depositing a second oxide layer over the first oxide layer in a second deposition process that is different from the first deposition process. In some embodiments, the first deposition process is an atomic layer deposition (ALD) process, and the second deposition process is a flowable chemical vapor deposition (FCVD) process. In some embodiments, the first oxide layer has a different density than the second oxide layer. In some embodiments, the method further includes laterally recessing the first semiconductor layers during the partially recessing of the oxide layer. In some embodiments, after the selectively removing of the oxide layer, a ratio of a smallest thickness and a largest thickness of one of the first semiconductor layers is between about 0.95 and about 0.98. In some embodiments, the method further includes depositing a buffer epitaxial layer in the first trench, and forming a bottom isolation layer between the buffer epitaxial layer and the source/drain feature. The source/drain feature has a dopant concentration higher than that of the buffer epitaxial layer.

In yet another exemplary aspect, the present disclosure is directed to a structure. The structure includes a plurality of nanostructures vertically stacked above a substrate, a gate structure wrapping around each of the plurality of nanostructures, a gate spacer layer disposed on sidewalls of the gate structure, a source/drain feature abutting the plurality of nanostructures, inner spacer features interposed between the gate structure and the source/drain feature and extending between two adjacent ones of the plurality of nanostructures, wherein the inner spacer features include a sidewall facing the gate structure, and a dielectric feature in contact with the sidewall of the inner spacer features and in contact with the two adjacent ones of the plurality of nanostructures. The inner spacer features and the dielectric feature include different compositions. In some embodiments, the inner spacer features include a nitride, and the dielectric feature includes an oxide. In some embodiments, the dielectric feature includes a first oxide layer in contact with the two adjacent ones of the plurality of nanostructures and a second oxide layer in contact with the inner spacer features, and the first oxide layer has a lower oxide concentration than the second oxide layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming over a substrate a stack that includes a plurality of channel layers interleaved by a plurality of sacrificial layers;
patterning the stack to form a fin-shaped structure;
forming a dummy gate stack over a channel region of the fin-shaped structure;
depositing a gate spacer layer over the dummy gate stack;
after the depositing of the gate spacer layer, recessing a source/drain region of the fin-shaped structure to form a source/drain trench;
selectively removing the plurality of sacrificial layers in the channel region to release the plurality of channel layers as a plurality of channel members;
depositing a dielectric dummy layer between the plurality of channel members;
laterally recessing the dielectric dummy layer to form inner spacer recesses;
depositing an inner spacer layer over the inner spacer recesses;
etching back the inner spacer layer to form inner spacer features in the inner spacer recesses;
forming a source/drain feature in the source/drain region;
after the forming of the source/drain feature, removing the dummy gate stack;
removing the dielectric dummy layer to release the plurality of channel members; and
forming a gate structure to wrap around each of the plurality of channel members.

2. The method of claim 1, wherein the dielectric dummy layer includes silicon oxide.

3. The method of claim 1, wherein, during the depositing of the dielectric dummy layer, end portions of the plurality of channel members are oxidized.

4. The method of claim 3, wherein the laterally recessing of the dielectric dummy layer also laterally recesses the oxidized end portions of the plurality of channel members.

5. The method of claim 1, wherein, during the laterally recessing of the dielectric dummy layer, a bottom surface of the gate spacer layer is exposed.

6. The method of claim 5, wherein the source/drain feature is in contact with the bottom surface of the gate spacer layer.

7. The method of claim 1, further comprising:
depositing a contact etch stop layer (CESL) over the source/drain feature;
depositing an interlayer dielectric (ILD) layer over the CESL;
selectively recessing the ILD layer to form a top recess; and
depositing a capping layer over the top recess.

8. The method of claim 7, wherein a composition of the capping layer is different from a composition of the dielectric dummy layer.

9. The method of claim 1, wherein the gate structure has an upper portion laterally stacked between opposing sidewalls of the gate spacer layer and a lower portion vertically stacked between two adjacent ones of the plurality of channel members, and a first width of the upper portion of the gate structure is larger than a second width of the lower portion of the gate structure.

10. The method of claim 9, wherein a ratio of the second width over the first width is between about 0.8 and about 0.95.

11. A method, comprising:
forming a stack that includes a plurality of first semiconductor layers of a first semiconductor material interleaved by a plurality of second semiconductor layers of a second semiconductor material that is different from the first semiconductor material;
patterning the stack to form a fin-shaped structure;
forming a dummy gate stack over a first region of the fin-shaped structure;
depositing a gate spacer layer over sidewalls of the dummy gate stack;
after the depositing of the gate spacer layer, recessing a second region of the fin-shaped structure to form a first trench;
selectively removing the second semiconductor layers in the first region to release the first semiconductor layers;
depositing an oxide layer in space among the first semiconductor layers;
partially recessing the oxide layer to form inner spacer recesses;
forming inner spacer features in the inner spacer recesses;
forming a source/drain feature in the first trench;
removing the dummy gate stack to form a second trench;
selectively removing the oxide layer from the second trench; and
forming a gate structure in the second trench to engage the first semiconductor layers.

12. The method of claim 11, wherein the depositing of the oxide layer includes depositing a first oxide layer in a first deposition process and depositing a second oxide layer over the first oxide layer in a second deposition process that is different from the first deposition process.

13. The method of claim 12, wherein the first deposition process is an atomic layer deposition (ALD) process, and the second deposition process is a flowable chemical vapor deposition (FCVD) process.

14. The method of claim 12, wherein the first oxide layer has a different density than the second oxide layer.

15. The method of claim 11, further comprising:
laterally recessing the first semiconductor layers during the partially recessing of the oxide layer.

16. The method of claim 11, wherein, after the selectively removing of the oxide layer, a ratio of a smallest thickness and a largest thickness of one of the first semiconductor layers is between about 0.95 and about 0.98.

17. The method of claim 11, further comprising:
depositing a buffer epitaxial layer in the first trench; and
forming a bottom isolation layer between the buffer epitaxial layer and the source/drain feature,
wherein the source/drain feature has a dopant concentration higher than that of the buffer epitaxial layer.

18. A structure, comprising:
a plurality of nanostructures vertically stacked above a substrate;
a gate structure wrapping around each of the plurality of nanostructures;
a gate spacer layer disposed on sidewalls of the gate structure;
a source/drain feature abutting the plurality of nanostructures;
inner spacer features interposed between the gate structure and the source/drain feature and extending between two adjacent ones of the plurality of nanostructures, wherein the inner spacer features include a sidewall facing the gate structure; and
a dielectric feature in contact with the sidewall of the inner spacer features and in contact with the two adjacent ones of the plurality of nanostructures, wherein the inner spacer features and the dielectric feature include different compositions.

19. The structure of claim 18, wherein the inner spacer features include a nitride, and the dielectric feature includes an oxide.

20. The structure of claim 18, wherein the dielectric feature includes a first oxide layer in contact with the two adjacent ones of the plurality of nanostructures and a second oxide layer in contact with the inner spacer features, and the first oxide layer has a lower oxide concentration than the second oxide layer.
